(19) United States
(12) Patent Application Publication
(10) Pub. No.: US 2025/0212563 A1
(43) Pub. Date: Jun. 26, 2025

(54) LIGHT EMITTING DEVICE

(71) Applicant: SONY GROUP CORPORATION, TOKYO (JP)

(72) Inventor: NAOKI HIRAO, TOKYO (JP)

(21) Appl. No.: 18/847,630

(22) PCT Filed: Feb. 9, 2023
(86) PCT No.: PCT/JP2023/004423

§ 371 Date: Sep. 16, 2024

(30) Foreign Application Priority Data
Mar. 24, 2022 (JP) 2022-048801

(51) Int. Cl. H10H 20/81; H10H 20/816; H10H 20/825; H10H 20/855; H10H 29/14

(52) U.S. Cl. CPC H10H 20/8215; H10H 20/816; H10H 20/8252; H10H 20/855; H10H 29/142

(57) ABSTRACT

A light emitting device according to an embodiment of the present disclosure includes: a first electrically-conductive layer (10) that is of a first electrically-conductive type; a first high resistance part (51) that is provided in the first electrically-conductive layer (10) and that includes first atoms; a second electrically-conductive layer (20) that is of a second electrically-conductive type; a second high resistance part (52) that is provided in the second electrically-conductive layer (20) and that includes second atoms; and an active layer (30) that is provided between the first electrically-conductive layer (10) and the second electrically-conductive layer (20). A concentration of the first atoms inside the first high resistance part (51) is greater than a concentration of the first atoms in a first surface (11S1) of the first electrically-conductive layer (10).

### TECHNICAL FIELD

The present disclosure relates to a light emitting device.

### BACKGROUND ART

A light emitting element provided with electric current constriction layers having high resistance above and below an n-type clad layer and a p-type clad layer, respectively, has been proposed (PTL 1).

### CITATION LIST

### Patent Literature

PTL 1: Japanese Unexamined Patent Application Publication (Published Japanese Translation of PCT Application) No. JP 2001-223384

### SUMMARY OF THE INVENTION

It is demanded that a light emitting device efficiently emit light.

It is desired to provide a light emitting device configured to efficiently emit light.

A light emitting device according to an embodiment of the present disclosure includes: a first electrically-conductive layer that is of a first electrically-conductive type; a first high resistance part that is provided in the first electrically-conductive layer and that includes first atoms; a second electrically-conductive layer that is of a second electrically-conductive type; a second high resistance part that is provided in the second electrically-conductive layer and that includes second atoms; and an active layer that is provided between the first electrically-conductive layer and the second electrically-conductive layer. A concentration of the first atoms inside the first high resistance part is greater than a concentration of the first atoms in a first surface of the first electrically-conductive layer.

### BRIEF DESCRIPTION OF DRAWING

FIG. 1 is a diagram illustrating a configuration example of a light emitting device according to an embodiment of the present disclosure.

FIG. 2 is a diagram illustrating an example of a concentration of injected atoms in the light emitting device according to the embodiment of the present disclosure.

FIG. 3 is a diagram illustrating an example of concentrations of injected atoms in the light emitting device according to the embodiment of the present disclosure.

FIG. 4 is a diagram illustrating another example of concentrations of injected atoms in the light emitting device according to the embodiment of the present disclosure.

FIG. 5 is a diagram illustrating an example of a plan configuration of the light emitting device according to the embodiment of the present disclosure.

FIG. 6 is a diagram illustrating an example of a cross-sectional configuration of the light emitting device according to the embodiment of the present disclosure.

FIG. 7 is a diagram illustrating an example of concentrations of injected atoms in a light emitting device according to Modification Example 1 of the present disclosure.

FIG. 8 is a diagram illustrating another example of concentrations of injected atoms in the light emitting device according to Modification Example 1 of the present disclosure.

FIG. 9 is a diagram illustrating a configuration example of a light emitting device according to Modification Example 2 of the present disclosure.

FIG. 10 is a diagram illustrating another configuration example of the light emitting device according to Modification Example 2 of the present disclosure.

FIG. 11 is a diagram illustrating a configuration example of a light emitting device according to Modification Example 3 of the present disclosure.

FIG. 12 is a diagram illustrating another configuration example of the light emitting device according to Modification Example 3 of the present disclosure.

FIG. 13 is a diagram illustrating a configuration example of a light emitting device according to Modification Example 4 of the present disclosure.

FIG. 14 is a diagram illustrating another configuration example of the light emitting device according to Modification Example 4 of the present disclosure.

FIG. 15 is a diagram illustrating another configuration example of the light emitting device according to Modification Example 4 of the present disclosure.

FIG. 16 is a diagram illustrating a configuration example of a light emitting device according to Modification Example 5 of the present disclosure.

### MODES FOR CARRYING OUT THE INVENTION

In the following, an embodiment of the present disclosure will be described in detail with reference to the drawings. It is to be noted that the description will be given in the following order.
1. Embodiment
2. Modification Examples
2-1. Modification Example 1
2-2. Modification Example 2
2-3. Modification Example 3
2-4. Modification Example 4
2-5. Modification Example 5

### 1. Embodiment

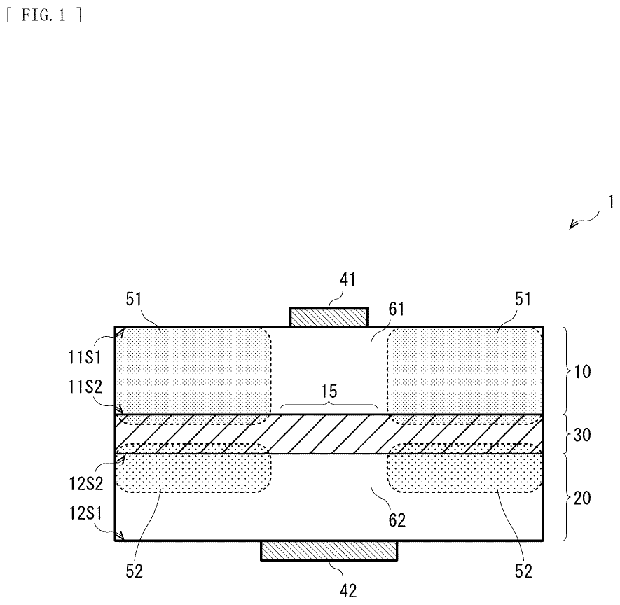

FIG. 1 is a diagram illustrating a configuration example of a light emitting device according to an embodiment of the present disclosure. A light emitting device 1 is a device configured to emit light. The light emitting device 1 may be applied to a red light emitting diode (LED), for example. It is possible to utilize the light emitting device 1 in various types of light emitting devices including light emitting diodes and light emitting lasers, for example.

The light emitting device 1 includes a first electrically-conductive layer 10, a second electrically-conductive layer 20, and an active layer 30. The light emitting device 1 has, as illustrated in the example in FIG. 1, a configuration layered with the first electrically-conductive layer 10, the active layer 30, and the second electrically-conductive layer 20. The active layer 30 is provided between the first electrically-conductive layer 10 and the second electrically-conductive layer 20. Furthermore, the light emitting device 1 includes, as illustrated in FIG. 1, a first electrode 41 and a second electrode 42.

The first electrically-conductive layer 10 has, as illustrated in FIG. 1, a first surface 11S1 and a second surface 11S2 opposed to each other. The second surface 11S2 is a surface on a side opposite to the first surface 11S1. The first electrode 41 is provided on a side of the first surface 11S1 of the first electrically-conductive layer 10, and the active layer 30 is provided on the side of the second surface 11S2 of the first electrically-conductive layer 10.

The second electrically-conductive layer 20 has, as illustrated in FIG. 1, a first surface 12S1 and a second surface 12S2 opposed to each other. The second surface 12S2 is a surface on a side opposite to the first surface 12S1. The second electrode 42 is provided on a side of the first surface 12S1 of the second electrically-conductive layer 20, and the active layer 30 is provided on the side of the second surface 12S2 of the second electrically-conductive layer 20. It is possible to also say that the first electrically-conductive layer 10 and the second electrically-conductive layer 20 are disposed to pinch the active layer 30.

The first electrically-conductive layer 10, the second electrically-conductive layer 20, and the active layer 30 each include a III-V group chemical compound semiconductor material, for example. The first electrically-conductive layer 10 and the second electrically-conductive layer 20 are clad layers, and are of electrically-conductive types that are different from each other. For example, the first electrically-conductive layer 10 is a p-type electrically-conductive layer, and is a semiconductor layer formed by using a p-type impurity. The second electrically-conductive layer 20 is an n-type electrically-conductive layer, and is a semiconductor layer formed by using an n-type impurity. It is possible to also say that the first electrically-conductive layer 10 and the second electrically-conductive layer 20 are a p-type clad layer and an n-type clad layer, respectively.

The first electrically-conductive layer 10, the second electrically-conductive layer 20, and the active layer 30 are formed by using GaN (gallium nitride), as an example. The first electrically-conductive layer 10 is doped (added) with Mg (magnesium) as the p-type impurity, for example. The first electrically-conductive layer 10 includes p-GaN doped with Mg. The second electrically-conductive layer 20 is doped (added) with Si (silicon) as the n-type impurity, for example. The second electrically-conductive layer 20 includes n-GaN doped with Si.

The first electrically-conductive layer 10, the second electrically-conductive layer 20, and the active layer 30 may be formed by using AlGalnP (aluminum gallium indium phosphorus). In this case, the first electrically-conductive layer 10 is added with Mg as the p-type impurity, for example. The first electrically-conductive layer 10 includes p-AlGaInP doped with Mg. The second electrically-conductive layer 20 is added with Si as the n-type impurity, for example. The second electrically-conductive layer 20 includes n-AlGaInP doped with Si.

Note that the first electrically-conductive layer 10, the second electrically-conductive layer 20, and the active layer 30 may include GaAs, AlGaAs, or InGaAs or another semiconductor material, for example. As the p-type impurity, Zn (zinc) may be used. Note that the first electrically-conductive layer 10 and the second electrically-conductive layer 20 may not be partially doped, and may include a portion that has not yet been doped (for example, a barrier layer).

As the first electrically-conductive layer 10 and the second electrically-conductive layer 20, undoped (nondoped) semiconductor layers may be used. That is, the first electrically-conductive layer 10 and the second electrically-conductive layer 20 may be i-type semiconductor layers. For example, the light emitting device 1 may include a first electrically-conductive layer 10 that is a p-type semiconductor layer and a second electrically-conductive layer 20 that is an i-type semiconductor layer. Furthermore, for example, the light emitting device 1 may include a first electrically-conductive layer 10 that is an i-type semiconductor layer and a second electrically-conductive layer 20 that is an n-type semiconductor layer.

The active layer 30 is positioned between the first electrically-conductive layer 10 and the second electrically-conductive layer 20, and is supplied with carriers (electrical charges) from the electrodes. The active layer 30 may be supplied with carriers by the first electrically-conductive layer 10 and the second electrically-conductive layer 20, generating light. The active layer 30 is a light emitting layer, and is configured to generate light as an electric current is supplied.

The active layer 30 may be a single layer or may be layered with a plurality of layers. The active layer 30 may include a plurality of well layers and a plurality of barrier layers to have a multi quantum well (MQW) structure.

The first electrode 41 is electrically coupled to the first electrically-conductive layer 10, and is configured to supply a voltage (an electric current) to the first electrically-conductive layer 10. The first electrode 41 includes a metal material such as Ni (nickel), Pt (platinum), or Au (gold). The first electrode 41 may include another metal material, or may include a transparent electrode including ITO (indium tin oxide), for example.

The second electrode 42 is electrically coupled to the second electrically-conductive layer 20, and is configured to supply a voltage (an electric current) to the second electrically-conductive layer 20. The second electrode 42 includes, for example, Ti (titanium), Pt, Au, Ni, or AuGe (gold germanium). Note that the second electrode 42 may also include a transparent electrode including ITO, for example.

The first electrically-conductive layer 10 is provided with a first high resistance part 51 having a first opening 61, as illustrated in FIG. 1. The first high resistance part 51 is formed through ion injection, and has high electric resistance. For example, atoms that inactivate the first electrically-conductive layer 10 doped with an impurity are selectively injected into the first electrically-conductive layer 10 to form the first high resistance part 51 and the first opening 61. For example, H (hydrogen), He (helium), or B (boron) is ion-injected to form the first high resistance part 51 having high resistance.

The first high resistance part 51 is a first ion injection part, and includes hydrogen atoms, helium atoms, or boron atoms, for example. The first high resistance part 51 includes, as an impurity, hydrogen atoms or the like that are selectively ion-injected into the first electrically-conductive layer 10, and may also be referred to as an impurity region having a high impurity concentration.

The first high resistance part 51 is formed to have a higher resistance value than a resistance value of an adjacent medium. In the example illustrated in FIG. 1, the first high resistance part 51 has a resistance value greater than a resistance value of a portion, of the first electrically-conductive layer 10, where the first high resistance part 51 is not present, that is, the first opening 61. The light emitting device 1 has, as a low resistance part, the first opening 61 defined by the first high resistance part 51.

The second electrically-conductive layer 20 is provided with a second high resistance part 52 having a second opening 62, as illustrated in FIG. 1. The second high resistance part 52 is formed through ion injection, and has high electric resistance. For example, atoms that inactivate the second electrically-conductive layer 20 doped with an impurity are selectively injected into the second electrically-conductive layer 20 to form the second high resistance part 52 and the second opening 62. For example, H, He, or B is ion-injected to form the second high resistance part 52 having high resistance.

The second high resistance part 52 is a second ion injection part, and includes hydrogen atoms, helium atoms, or boron atoms, for example. The second high resistance part 52 includes, as an impurity, hydrogen atoms or the like that are selectively ion-injected into the second electrically-conductive layer 20, and may also be referred to as an impurity region having a high impurity concentration.

The second high resistance part 52 is formed to have a higher resistance value than a resistance value of an adjacent medium. In the example illustrated in FIG. 1, the second high resistance part 52 has a resistance value greater than a resistance value of a portion, of the second electrically-conductive layer 20, where the second high resistance part 52 is not present, that is, the second opening 62. The light emitting device 1 has, as a low resistance part, the second opening 62 defined by the second high resistance part 52.

Furthermore, in the present embodiment, the first high resistance part 51 is disposed, as illustrated in FIG. 1, in a portion of the first electrically-conductive layer 10 and a portion of the active layer 30. The first high resistance part 51 is formed over an area from the first electrically-conductive layer 10 to the portion of the active layer 30. The second high resistance part 52 is disposed in a portion of the second electrically-conductive layer 20 and a portion of the active layer 30. The second high resistance part 52 is formed over an area from the second electrically-conductive layer 20 to the portion of the active layer 30.

As a voltage is supplied between the first electrode 41 and the second electrode 42, electrical charges (for example, holes) supplied by the first electrode 41 and the first electrically-conductive layer 10 and electrical charges (for example, electrons) supplied by the second electrode 42 and the second electrically-conductive layer 20 are supplied to the active layer 30. The light emitting device 1 may generate light through recombination of the electrons and the holes in the active layer 30 to externally emit the light.

In the light emitting device 1 provided with the first high resistance part 51 and the second high resistance part 52, an electric current supplied by the first electrode 41 and the second electrode 42 is constricted. Constricting a route for an electric current between the first electrode 41 and the second electrode 42 makes it possible to allow the electric current to mainly flow through the first opening 61 and the second opening 62 and to be concentrated into carriers in a certain region (a light emitting region 15) in the active layer 30.

In the light emitting device 1, an electric current constriction structure including high resistance parts and openings causes carriers to be supplied to the light emitting region 15 illustrated in FIG. 1. The light emitting region 15 is a region configured to emit light. The light emitting region 15 is a region corresponding to the first opening 61 and the second opening 62. As described above, the light emitting device 1 according to the present embodiment may have the electric current constriction structure, and may efficiently supply an electric current to the light emitting region 15 in the active layer 30.

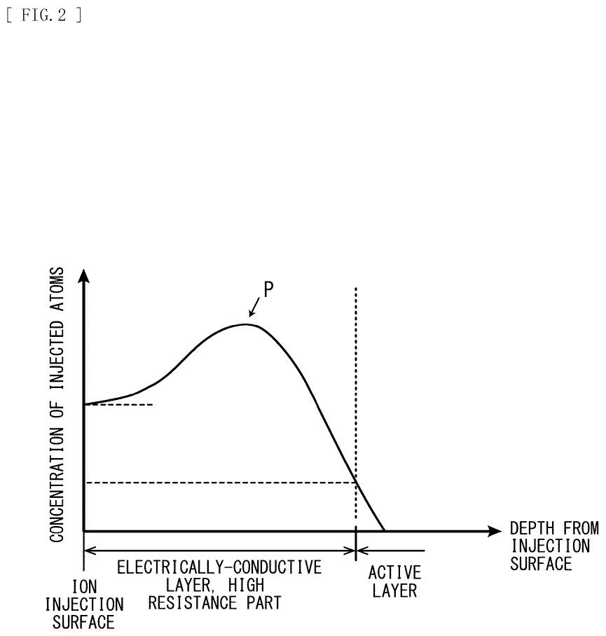

FIG. 2 is a diagram illustrating an example of a concentration of injected atoms in the light emitting device according to the present embodiment. In FIG. 2, a vertical axis indicates a concentration of injected atoms that are ion-injected atoms (for example, hydrogen atoms described above). Furthermore, a horizontal axis indicates a depth from an ion injection surface (a position). Such a distribution of concentration is measured through secondary ion mass spectrometry (SIMS), for example.

In the present embodiment, ion injection conditions (for example, an acceleration voltage, a period of injection time, and an ion type) are set and ion injection is performed to acquire a distribution of concentration illustrated in FIG. 2. For example, in a case where an ion injection surface is the first surface 11S1 of the first electrically-conductive layer 10, a concentration of atoms having undergone ion injection into the first electrically-conductive layer 10 becomes greater inside the first high resistance part 51 than a concentration of atoms in the first surface 11S1 of the first electrically-conductive layer 10. In the first electrically-conductive layer 10 and the first high resistance part 51, a concentration of injected atoms in a portion away from the first surface 11S1 becomes greater than a concentration of injected atoms in a portion close to the first surface 11S1. The first high resistance part 51 has, between the first surface 11S1 and the second surface 11S2 of the first electrically-conductive layer 10, as illustrated in the example in FIG. 2, a peak (apex) P in concentration of injected atoms. This makes it possible to achieve a light emitting device configured to efficiently emit light.

Furthermore, also in a case where an ion injection surface is the first surface 12S1 of the second electrically-conductive layer 20, for example, ion injection conditions are set and ion injection is performed to acquire the distribution of concentration illustrated in FIG. 2. A concentration of atoms having undergone ion injection into the second electrically-conductive layer 20 becomes greater inside the second high resistance part 52 than a concentration of atoms in the first surface 12S1 of the second electrically-conductive layer 20. In the second electrically-conductive layer 20 and the second high resistance part 52, a concentration of injected atoms in a portion away from the first surface 12S1 becomes greater than a concentration of injected atoms in a portion close to the first surface 12S1. The second high resistance part 52 has, between the first surface 12S1 and the second surface 12S2 of the second electrically-conductive layer 20, a peak (apex) P in concentration of injected atoms. This makes it possible to improve light emitting efficiently.

In the example illustrated in FIG. 2, a distribution of concentration of injected atoms in a depth direction from the ion injection surface has a concentration gradient (a tail) causing the concentration to gradually decrease from a position of the peak P to a side of the ion injection surface. Furthermore, the concentration of injected atoms plummets in concentration from the position of the peak P to a side of the active layer 30, as illustrated in FIG. 2.

If a concentration of injected atoms in a high resistance part (the first high resistance part 51 or the second high resistance part 52) is low, it is conceivable that a resistance value of the high resistance part becomes insufficient, and an electric current is not properly constricted. Carriers supplied by the first electrode 41 and the second electrode 42 may flow out of end faces (peripheral faces) and may thus be lost, possibly resulting in decreases in ratio of an electric current contributing to emission of light (electric current efficiency). Furthermore, in a case where more ions are injected into the active layer 30, the active layer 30 may be damaged due to the ion injection, possibly making it impossible to efficiently emit light.

To address these issues, in the light emitting device 1 having a peak in concentration of injected atoms in each of the first electrically-conductive layer 10 and the second electrically-conductive layer 20, the first high resistance part 51 and the second high resistance part 52 fully having high resistance make it possible to introduce carriers into the light emitting region 15. The light emitting device 1 thus makes it possible to properly constrict an electric current, making it possible to suppress occurrence of decreases in electric current efficiency. Furthermore, it is possible to suppress damage in the active layer 30, which makes it possible to suppress occurrence of degradation in characteristics of the active layer 30.

Furthermore, in the present embodiment, as illustrated in the example in FIG. 2, a concentration of injected atoms in the active layer 30 is smaller than the concentration of injected atoms in the ion injection surface (for example, the first surface 11S1 of the first electrically-conductive layer 10). This makes it possible to effectively suppress damage in the active layer 30. In a case where the active layer 30 has a multi quantum well (MQW) structure including a plurality of light emitting layers, a concentration of injected atoms in one light emitting layer (hereinafter referred to as a layer of interest) that is caused to mainly emit light among the plurality of light emitting layers, a concentration of injected atoms in an ion injection surface may be decreased. It is thus possible to effectively suppress occurrence of degradation in characteristics of the active layer 30.

A concentration of injected atoms in a surface of the active layer 30, that is, a surface, of the active layer 30, opposed to the second surface 11S2 of the first electrically-conductive layer 10 (or a surface, of the active layer 30, opposed to the second surface 12S2 of the second electrically-conductive layer 20) may be equal to or greater than 1×10¹⁴ atm/cm³. This makes it possible to fully increase a resistance value of a high resistance part to constrict an electric current, making it possible to effectively suppress decreases in electric current efficiency.

Furthermore, in the example illustrated in FIG. 1, the first high resistance part 51 is provided over an area from the first electrically-conductive layer 10 to a portion of the active layer 30, and the second high resistance part 52 is provided over an area from the second electrically-conductive layer 20 to a portion of the active layer 30. This makes it possible to suppress decreases in electric current efficiency while suppressing degradation in characteristics of the active layer 30.

A size of the light emitting region 15 in the active layer 30 in the light emitting device 1 may have a size equal to or smaller than 10 μm. Even in this case, as the first high resistance part 51 and the second high resistance part 52 each having such a distribution of concentration as described above are provided, it is possible to suppress decreases in electric current efficiency. It is thus possible to prevent the above-described increases in disappearing of carriers on an end face due to that the light emitting device 1 has been decreased in size, making it possible to suppress decreases in electric current efficiency. A size of the light emitting region 15 in the active layer 30 may be equal to or smaller than 20 μm or equal to or smaller than 30 μm.

Note that ion injection may be performed from the side of the first surface 11S1 of the first electrically-conductive layer 10, or ion injection may be performed from the side of the first surface 12S1 of the second electrically-conductive layer 20. Furthermore, ion injection from the side of the first surface 11S1 of the first electrically-conductive layer 10 and ion injection from the side of the first surface 12S1 of the second electrically-conductive layer 20 may be performed.

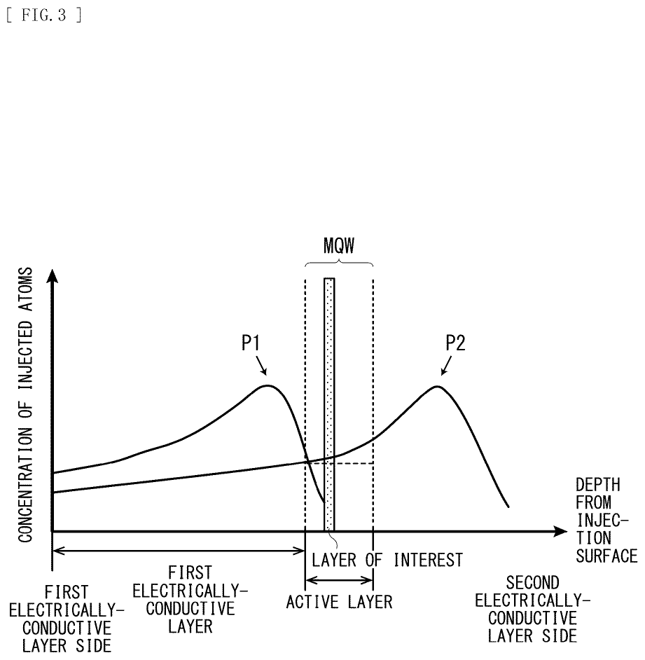

For example, to acquire such a distribution of concentration illustrated in FIG. 3, ion injection may be performed from the side of the first surface 11S1 of the first electrically-conductive layer 10 into the first electrically-conductive layer 10 and the second electrically-conductive layer 20. FIG. 3 illustrates, in a case where ion injection is performed from the side of the first surface 11S1 of the first electrically-conductive layer 10 into the first electrically-conductive layer 10 and the second electrically-conductive layer 20, concentrations of injected atoms in the first electrically-conductive layer 10 and the second electrically-conductive layer 20. The first surface 11S1 of the first electrically-conductive layer 10 serves as an ion injection surface, and ion injection into the first electrically-conductive layer 10 and ion injection into the second electrically-conductive layer 20 are performed.

As illustrated in FIG. 3, the first high resistance part 51 has a peak P1 in concentration of injected atoms in a thickness direction of the first electrically-conductive layer 10. Furthermore, the second high resistance part 52 has a peak P2 in concentration of injected atoms in a thickness direction of the second electrically-conductive layer 20. The first electrically-conductive layer 10 and the second electrically-conductive layer 20 may be injected with an identical type of ions, or may be injected with different types of ions.

Furthermore, as illustrated in FIG. 3, ion injection into the first electrically-conductive layer 10 and ion injection into the second electrically-conductive layer 20 may be performed to achieve a smallest total concentration of injected atoms in the layer of interest among the first electrically-conductive layer 10 and the active layer 30. In the example illustrated in FIG. 3, a total concentration of injected atoms in the layer of interest is smallest within a range from the first surface 11S1 serving as an ion injection surface to the second surface 12S2. Decreasing a concentration of injected atoms in the layer of interest in the active layer 30 makes it possible to suppress decreases in light emitting characteristics.

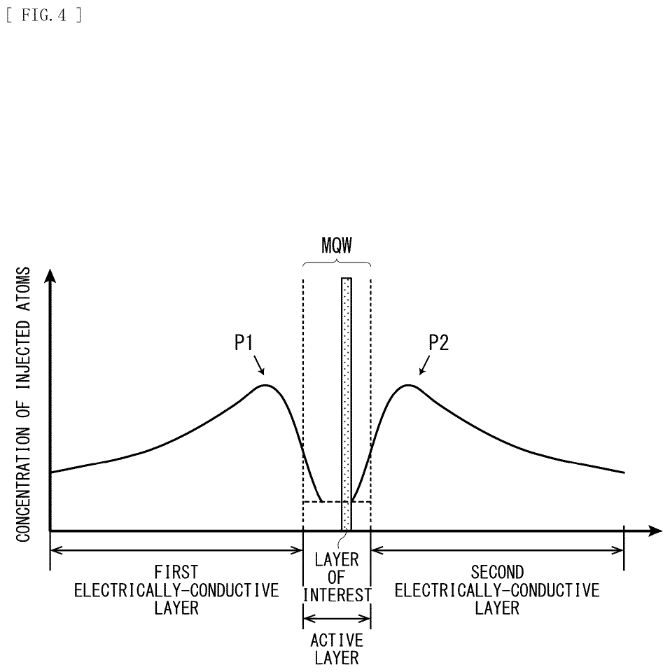

Furthermore, for example, to acquire such a distribution of concentration as illustrated in FIG. 4, ion injection from the side of the first surface 11S1 of the first electrically-conductive layer 10 and ion injection from the side of the first surface 12S1 of the second electrically-conductive layer 20 may be performed. In the example illustrated in FIG. 4, the first surface 11S1 of the first electrically-conductive layer 10 and the first surface 12S1 of the second electrically-conductive layer 20 serve as ion injection surfaces. In this case, it is possible to decrease a concentration of injected atoms in the layer of interest in the active layer 30, making it possible to effectively suppress decreases in light emitting characteristics.

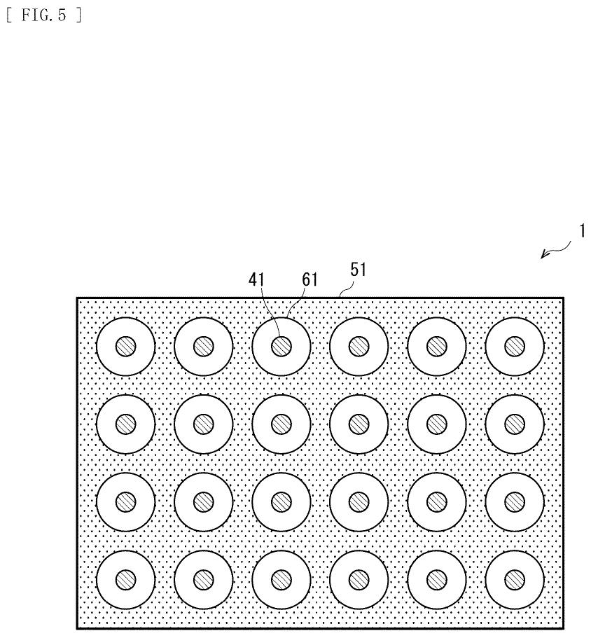

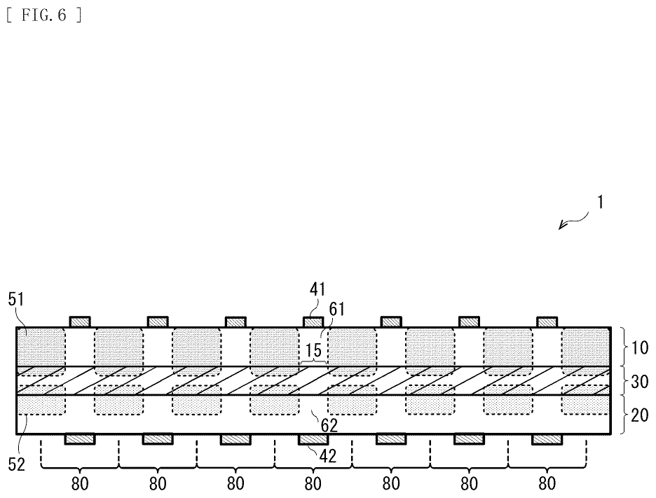

FIG. 5 is a diagram illustrating an example of a plan configuration of the light emitting device according to the present embodiment. FIG. 6 is a diagram illustrating an example of a cross-sectional configuration of the light emitting device. The light emitting device 1 may include a plurality of elements (structure bodies) 80 including the first electrically-conductive layer 10, the active layer 30, and the second electrically-conductive layer 20. The elements 80 are provided in a two dimensional shape, for example, as illustrated in FIGS. 5 and 6. The light emitting device 1 may also be said to include an element array in which the elements 80 are disposed in a matrix.

The first high resistance part 51 and the second high resistance part 52 are provided to surround the light emitting region 15 in the active layer 30. In the example illustrated in FIG. 5, the first openings 61 and the second openings 62 each have a circular shape. It is possible to appropriately change the shapes of the first openings 61 and the second openings 62, and the shapes may be polygonal shapes or other shapes.

As described above, the light emitting device 1 has the element array including the plurality of elements 80. Each of the elements 80 are provided with the first electrode 41 and the second electrode 42, as illustrated in FIGS. 5 and 6. The light emitting device 1 is configured to control emission of light per each of the elements 80, and to extract light per each of the elements 80.

### [Workings and Effects]

The light emitting device (the light emitting device 1) according to the present embodiment includes: the first electrically-conductive layer (the first electrically-conductive layer 10) that is of the first electrically-conductive type; the first high resistance part (the first high resistance part 51) that is provided in the first electrically-conductive layer and that includes the first atoms; the second electrically-conductive layer (the second electrically-conductive layer 20) that is of the second electrically-conductive type; the second high resistance part (the second high resistance part 52) that is provided in the second electrically-conductive layer and that includes the second atoms; and the active layer (the active layer 30) provided between the first electrically-conductive layer and the second electrically-conductive layer. The concentration of the first atoms inside the first high resistance part is greater than the concentration of the first atoms in the first surface (the first surface 11S1) of the first electrically-conductive layer.

In the light emitting device 1 according to the present embodiment, the concentration of injected atoms inside the first high resistance part 51 is greater than the concentration of injected atoms in the first surface 11S1 of the first electrically-conductive layer 10. The first high resistance part 51 has the peak (apex) P in concentration of injected atoms between the first surface 11S1 and the second surface 11S2 of the first electrically-conductive layer 10. Therefore, it is possible to properly constrict an electric current, making it possible to suppress decreases in electric current efficiency. It is thus possible to achieve a light emitting device configured to efficiently emit light.

Next, modification examples of the present disclosure will now be described herein. Like reference numerals designate identical or similar components in the embodiment described above, and some descriptions are thus appropriately omitted below.

### 2. Modification Examples

### 2-1. Modification Example 1

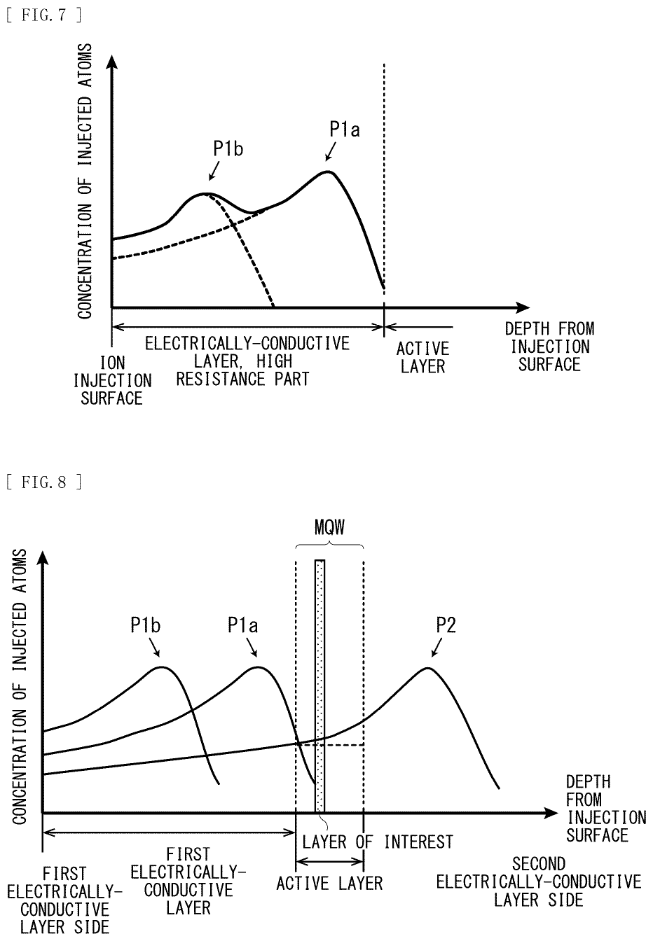

FIGS. 7 and 8 are diagrams illustrating examples of concentrations of injected atoms in a light emitting device according to Modification Example 1. The light emitting device 1 may have two or more peaks in concentration of atoms between the first surface 11S1 and the second surface 11S2 of the first electrically-conductive layer 10. In the example illustrated in FIG. 7 or 8, a peak Pla and a peak Plb are, for example, peaks in concentration of atoms that are different in type from each other. The peak Pla is a peak in concentration of atoms injected relatively deeper, and the peak Plb is a peak in concentration of atoms injected relatively shallower. For example, it is possible to acquire the peak Pla through ion injection of hydrogen or helium that is relatively smaller in atomic number, and it is possible to acquire the peak Plb through ion injection of boron that is relatively larger in atomic number.

Note that, as illustrated in the example in FIG. 8, ion injection may be performed to achieve a smallest concentration of injected atoms in the layer of interest in the active layer 30. Furthermore, the light emitting device 1 may have two or more peaks in concentration of atoms between the first surface 12S1 and the second surface 12S2 of the second electrically-conductive layer 20. Even in a case of the present modification example, it is possible to acquire effects similar to the effects of the light emitting device according to the embodiment described above.

### 2-2. Modification Example 2

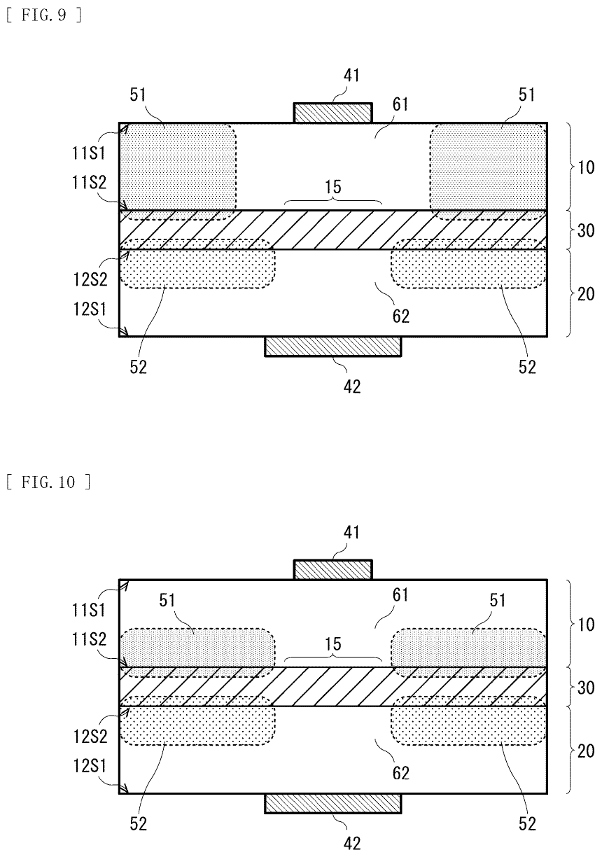

Although, in the embodiment described above, the configuration example of the light emitting device has been described, the configuration of the light emitting device is not limited to the example described above. FIGS. 9 and 10 are diagrams illustrating configuration examples of a light emitting device according to Modification Example 2. For example, as illustrated in the example in FIG. 9, a size of a region of the first high resistance part 51 and a size of a region of the second high resistance part 52 may be different from each other in the depth direction. The first opening 61 and the second opening 62 may have widths that are different from each other in a plane orthogonal to the depth direction. Furthermore, for example, as illustrated in FIG. 10, the first high resistance part 51 and the second high resistance part 52 may be formed only adjacent to the active layer 30.

### 2-3. Modification Example 3

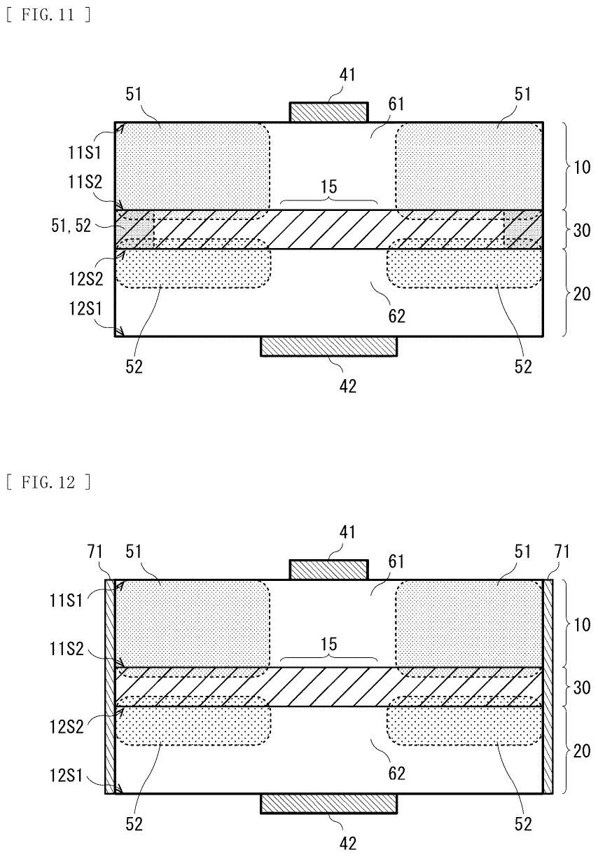

FIGS. 11 and 12 are diagrams illustrating configuration examples of a light emitting device according to Modification Example 3. As schematically illustrated in FIG. 11, high resistance parts (for example, the first high resistance part 51 and the second high resistance part 52) may be provided to each of end faces of the active layer 30 (in FIG. 11, a left end and a right end of the active layer 30). Furthermore, as illustrated in FIG. 12, protective films 71 configured to decrease disappearing of carriers may be provided on peripheral faces. In the example illustrated in FIG. 12, the protective films 71 are disposed on side surfaces of the first electrically-conductive layer 10, the second electrically-conductive layer 20, and the active layer 30.

### 2-4. Modification Example 4

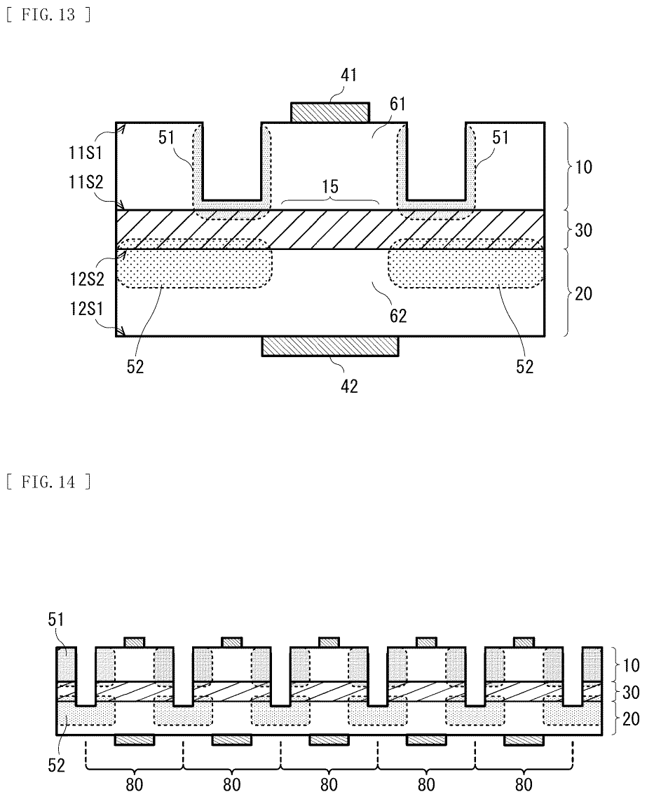

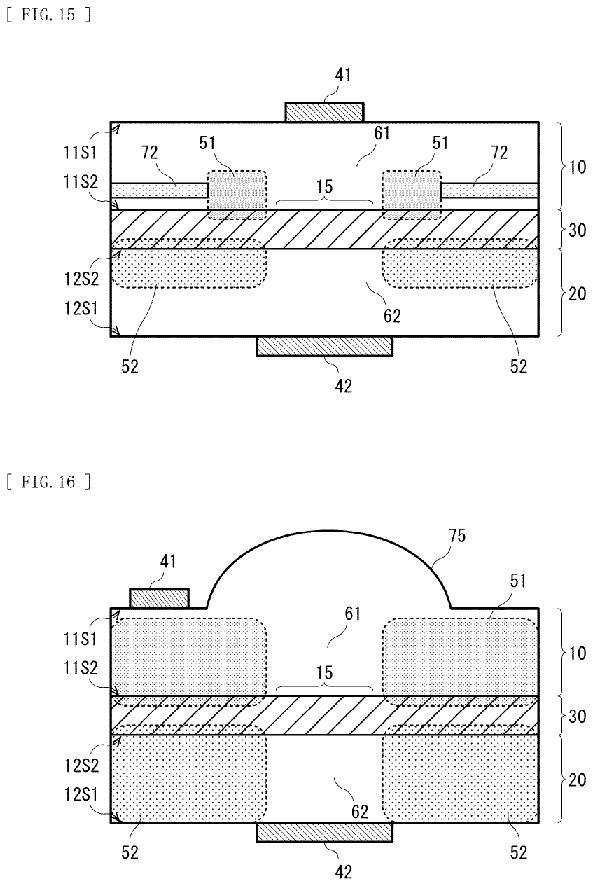

FIGS. 13 to 15 are diagrams illustrating configuration examples of a light emitting device according to Modification Example 4. In the light emitting device 1, as illustrated in the example in FIG. 13, the first electrically-conductive layer 10 may be partially removed through etching, and the first high resistance parts 51 may be formed through ion injection in the portion having undergone the removal. In this case, it is possible to use a lower acceleration voltage to inject heavier atoms at deeper positions. Note that the second electrically-conductive layer 20 may be partially removed through etching, and the second high resistance parts 52 may be formed through ion injection in the portion having undergone the removal. Furthermore, as illustrated in FIG. 14, the first electrically-conductive layer 10 and the active layer 30, for example, may be partially removed to cause the active layers 30 to be separated away from each other per each of the elements 80. Furthermore, as illustrated in FIG. 15, the light emitting device 1 may have an electric current constriction structure including high resistance parts and oxidation layers 72 formed through selective oxidation.

### 2-5. Modification Example 5

FIG. 16 is a diagram illustrating a configuration example of a light emitting device according to Modification Example 5. As illustrated in the example in FIG. 16, the first electrically-conductive layer 10 may include a lens part 75. The lens part 75 may include a material identical to a material of the first electrically-conductive layer 10. Providing the lens part 75 makes it possible to improve light extraction efficiently. Note that the second electrically-conductive layer 20 may be formed with a lens part. Note that one of the first electrode 41 or the second electrode 42 that is an electrode on a light extraction side may include a transparent electrode (for example, an ITO electrode). Even in this case, it is possible to improve light extraction efficiently.

Although the present disclosure has been described with reference to the embodiment and the modification examples, the present technique is not limited to the embodiment and the modification examples described above, but may be modified in a wide variety of ways. For example, although the modification examples described above have been described as modification examples of the embodiment described above, it is possible to appropriately combine the configurations of the modification examples.

The light emitting device according to the embodiment of the present disclosure includes: the first high resistance part that is provided in the first electrically-conductive layer and that includes the first atoms; and the second high resistance part that is provided in the second electrically-conductive layer and that includes the second atoms. The concentration of the first atoms is greater inside the first high resistance part than the concentration of the first atoms in the first surface of the first electrically-conductive layer. This makes it possible to properly constrict an electric current, making it possible to suppress decreases in electric current efficiency. It is thus possible to achieve a light emitting device configured to efficiently emit light.

Note that the effects described in the specification are mere examples. The effects of the technique are not limited to the effects described in the specification. There may be any other effects than those described herein. Furthermore, it is possible that the present disclosure has configurations described below.

(1)

A light emitting device including:
a first electrically-conductive layer that is of a first electrically-conductive type;
a first high resistance part that is provided in the first electrically-conductive layer and that includes first atoms;
a second electrically-conductive layer that is of a second electrically-conductive type;
a second high resistance part that is provided in the second electrically-conductive layer and that includes second atoms; and
an active layer that is provided between the first electrically-conductive layer and the second electrically-conductive layer,
in which
a concentration of the first atoms inside the first high resistance part is greater than a concentration of the first atoms in a first surface of the first electrically-conductive layer.
   (2)

The light emitting device according to (1), in which
the first electrically-conductive layer has the first surface, and a second surface on a side opposite to the first surface, and
the first high resistance part has a peak in concentration of the first atoms between the first surface and the second surface.
   (3)

The light emitting device according to (1) or (2), in which
the active layer is provided on a side of a second surface, of the first electrically-conductive layer, that is opposite to the first surface, and
a concentration of the first atoms in the active layer is smaller than the concentration of the first atoms in the first surface of the first electrically-conductive layer.
   (4)

The light emitting device according to any one of (1) to (3), in which a concentration of the first atoms in a surface of the active layer is equal to or greater than 1×10¹⁴ atm/cm³.

(5)

The light emitting device according to any one of (1) to (4), in which
the first high resistance part is provided over a portion of the first electrically-conductive layer and a portion of the active layer, and
the second high resistance part is provided over a portion of the second electrically-conductive layer and a portion of the active layer.
   (6)

The light emitting device according to any one of (1) to (5), in which a concentration of the second atoms inside the second high resistance part is greater than a concentration of the second atoms in a third surface of the second electrically-conductive layer.

(7)

The light emitting device according to (6), in which
the second electrically-conductive layer has the third surface, and a fourth surface on a side opposite to the third surface, and
the second high resistance part has a peak in concentration of the second atoms between the third surface and the fourth surface.
   (8)

The light emitting device according to (6) or (7), in which
the active layer is provided on a side of a fourth surface, of the second electrically-conductive layer, that is opposite to the third surface, and
a concentration of the second atoms in the active layer is smaller than the concentration of the second atoms in the third surface of the second electrically-conductive layer.
   (9)

The light emitting device according to any one of (1) to (8), in which the first atoms and the second atoms are each hydrogen atoms, helium atoms, or boron atoms.

(10)

The light emitting device according to any one of (1) to (9), in which the first atoms and the second atoms are atoms that are different in type from each other.

(11)

The light emitting device according to any one of (1) to (10), in which
the first electrically-conductive layer has the first surface, and a second surface on a side opposite to the first surface,
the first high resistance part includes the first atoms and third atoms, and
the first high resistance part has a first peak in concentration of the first atoms and a second peak in concentration of the third atoms between the first surface and the second surface.
   (12)

The light emitting device according to (11), in which
the second peak is positioned on a side of the first surface as compared with the first peak, and
an atomic number of the third atoms is greater than an atomic number of the first atoms.
   (13)

The light emitting device according to any one of (1) to (12), in which
the light emitting device includes
   a first electrode provided on a side of the first surface of the first electrically-conductive layer, and
   a second electrode provided on a side of a third surface of the second electrically-conductive layer, and
the first electrode, the second electrode, or both each include a transparent electrode.
   (14)

The light emitting device according to any one of (1) to (13), in which the first electrically-conductive layer or the second electrically-conductive layer includes a lens part.

(15)

The light emitting device according to any one of (1) to (14), in which
the first high resistance part and the second high resistance part are provided to surround a first region of the active layer, and
the first region includes a region configured to emit light.
   (16)

The light emitting device according to (15), in which the first region has a size equal to or smaller than 10 μm.

(17)

The light emitting device according to any one of (1) to (16), in which
the first high resistance part has a resistance value greater than a resistance value of a first opening defined by the first high resistance part, and
the second high resistance part has a resistance value greater than a resistance value of a second opening defined by the second high resistance part.
   (18)

The light emitting device according to any one of (1) to (17), in which a size of a first opening defined by the first high resistance part and a size of a second opening defined by the second high resistance part are different from each other.

(19)

The light emitting device according to any one of (1) to (18), wherein the light emitting device includes an array including a plurality of elements, the elements each including the first electrically-conductive layer, the second electrically-conductive layer, and the active layer.

(20)

A light emitting device including:
a first semiconductor layer;
a first high resistance part that is provided in the first semiconductor layer and that includes first atoms;
a second semiconductor layer;
a second high resistance part that is provided in the the second semiconductor layer and that includes second atoms; and
an active layer that is provided between the first semiconductor layer and the second semiconductor layer,
in which
a concentration of the first atoms inside the first high resistance part is greater than a concentration of the first atoms in a first surface of the first semiconductor layer.
   (21)

A light emitting device including:
a first electrically-conductive layer that is of a first electrically-conductive type;
a first ion injection part that is provided in the the first electrically-conductive layer and that includes first atoms;
a second electrically-conductive layer that is of a second electrically-conductive type;
a second ion injection part that is provided in the second electrically-conductive layer and that includes second atoms; and
an active layer that is provided between the first electrically-conductive layer and the second electrically-conductive layer,
in which
a concentration of the first atoms inside the first ion injection part is greater than a concentration of the first atoms in a first surface of the first electrically-conductive layer.
   (22)

A light emitting device including:
a first semiconductor layer;
a first ion injection part that is provided in the first semiconductor layer and that includes first atoms;
a second semiconductor layer;
a second ion injection part that is provided in the second semiconductor layer and that includes second atoms; and
an active layer that is provided between the first semiconductor layer and the second semiconductor layer,
in which
a concentration of the first atoms inside the first ion injection part is greater than a concentration of the first atoms in a first surface of the first semiconductor layer.

The present application claims the benefit of Japanese Priority Patent Application JP 2022-048801 filed with the Japan Patent Office on Mar. 24, 2022, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A light emitting device comprising:
a first electrically-conductive layer that is of a first electrically-conductive type;
a first high resistance part that is provided in the first electrically-conductive layer and that includes first atoms;
a second electrically-conductive layer that is of a second electrically-conductive type;
a second high resistance part that is provided in the second electrically-conductive layer and that includes second atoms; and
an active layer that is provided between the first electrically-conductive layer and the second electrically-conductive layer,
wherein
a concentration of the first atoms inside the first high resistance part is greater than a concentration of the first atoms in a first surface of the first electrically-conductive layer.

2. The light emitting device according to claim 1, wherein
the first electrically-conductive layer has the first surface, and a second surface on a side opposite to the first surface, and
the first high resistance part has a peak in concentration of the first atoms between the first surface and the second surface.

3. The light emitting device according to claim 1, wherein
the active layer is provided on a side of a second surface, of the first electrically-conductive layer, that is opposite to the first surface, and
a concentration of the first atoms in the active layer is smaller than the concentration of the first atoms in the first surface of the first electrically-conductive layer.

4. The light emitting device according to claim 1, wherein a concentration of the first atoms in a surface of the active layer is equal to or greater than 1×10¹⁴ atm/cm³.

5. The light emitting device according to claim 1, wherein
the first high resistance part is provided over a portion of the first electrically-conductive layer and a portion of the active layer, and
the second high resistance part is provided over a portion of the second electrically-conductive layer and a portion of the active layer.

6. The light emitting device according to claim 1, wherein a concentration of the second atoms inside the second high resistance part is greater than a concentration of the second atoms in a third surface of the second electrically-conductive layer.

7. The light emitting device according to claim 6, wherein
the second electrically-conductive layer has the third surface, and a fourth surface on a side opposite to the third surface, and
the second high resistance part has a peak in concentration of the second atoms between the third surface and the fourth surface.

8. The light emitting device according to claim 6, wherein
the active layer is provided on a side of a fourth surface, of the second electrically-conductive layer, that is opposite to the third surface, and
a concentration of the second atoms in the active layer is smaller than the concentration of the second atoms in the third surface of the second electrically-conductive layer.

9. The light emitting device according to claim 1, wherein the first atoms and the second atoms are each hydrogen atoms, helium atoms, or boron atoms.

10. The light emitting device according to claim 1, wherein the first atoms and the second atoms are atoms that are different in type from each other.

11. The light emitting device according to claim 1, wherein
the first electrically-conductive layer has the first surface, and a second surface on a side opposite to the first surface,
the first high resistance part includes the first atoms and third atoms, and
the first high resistance part has a first peak in concentration of the first atoms and a second peak in concentration of the third atoms between the first surface and the second surface.

12. The light emitting device according to claim 11, wherein
the second peak is positioned on a side of the first surface as compared with the first peak, and
an atomic number of the third atoms is greater than an atomic number of the first atoms.

13. The light emitting device according to claim 1, wherein
the light emitting device includes
a first electrode provided on a side of the first surface of the first electrically-conductive layer, and
a second electrode provided on a side of a third surface of the second electrically-conductive layer, and
the first electrode, the second electrode, or both each comprise a transparent electrode.

14. The light emitting device according to claim 1, wherein the first electrically-conductive layer or the second electrically-conductive layer includes a lens part.

15. The light emitting device according to claim 1, wherein
the first high resistance part and the second high resistance part are provided to surround a first region of the active layer, and
the first region comprises a region configured to emit light.

16. The light emitting device according to claim 15, wherein the first region has a size equal to or smaller than 10 μm.

17. The light emitting device according to claim 1, wherein
the first high resistance part has a resistance value greater than a resistance value of a first opening defined by the first high resistance part, and
the second high resistance part has a resistance value greater than a resistance value of a second opening defined by the second high resistance part.

18. The light emitting device according to claim 1, wherein a size of a first opening defined by the first high resistance part and a size of a second opening defined by the second high resistance part are different from each other.

19. The light emitting device according to claim 1, wherein the light emitting device includes an array including a plurality of elements, the elements each including the first electrically-conductive layer, the second electrically-conductive layer, and the active layer.

20. A light emitting device comprising:
a first electrically-conductive layer that is of a first electrically-conductive type;
a first ion injection part that is provided in the the first electrically-conductive layer and that includes first atoms;
a second electrically-conductive layer that is of a second electrically-conductive type;
a second ion injection part that is provided in the second electrically-conductive layer and that includes second atoms; and
an active layer that is provided between the first electrically-conductive layer and the second electrically-conductive layer,
wherein
a concentration of the first atoms inside the first ion injection part is greater than a concentration of the first atoms in a first surface of the first electrically-conductive layer.
